(19) United States
(12) Patent Application Publication
(10) Pub. No.: US 2010/0181192 A1
(43) Pub. Date: Jul. 22, 2010

(54) ANODE FOR PRODUCING A PLASMA BY WAY OF ELECTRIC ARC DISCHARGES

(76) Inventor: Carl-Friedrich Meyer, Dresden (DE)

Correspondence Address: JACOBSON HOLMAN PLLC, 400 SEVENTH STREET N.W., SUITE 600, WASHINGTON, DC, 20004, US

(21) Appl. No.: 12/451,052

(22) PCT Filed: Apr. 21, 2008
(86) PCT No.: PCT/DE2008/000728

§ 371 Date: Mar. 29, 2010

(30) Foreign Application Priority Data
Apr. 23, 2007 (DE) 10 2007 019 981.5

(51) Int. Cl. C23C 14/22

(52) U.S. Cl. 204/298.11; 204/298.14

(57) ABSTRACT

The invention relates to an anode for the formation of plasma by means of the development of electric arc discharges starting from a target connected as cathode for coating of substrates with target material in a vacuum. It is an object of the invention to propose a possibility by means of which the coating rate at least can be increased without substantially increasing the effort related to plant engineering required for this. The anode according to the invention for the plasma formation by means of the development of electric arc discharges starting from a target connected as cathode is then disposed in a known manner in a distance to the target. At the same time, anode bars are present initially disposed in parallel to the surface of the targets on the anode. In addition, strip-shaped elements being separated from each other by gaps are formed on the anode. Then, the strip-shaped elements start from the anode bars and face in the direction of a substrate to be coated on the surface. As a result, the formed plasma is enclosed with the strip-shaped elements of the anode from two opposing sides.

The invention relates to an anode for the formation of a plasma by means of the development of electric arc discharges starting from a target connected as cathode for coating of substrates with target material in a vacuum. The anodes according to the invention can be used for coating the surfaces of substrates with most different coating materials. At the same time, the formation of layer systems is also possible in which at least two of such layers can be developed on top of each another, and which are formed from different materials or substances. Thus, in particular the formation of layers of diamond-like carbon on substrate surfaces with the solution according to the invention is possible.

Conventionally, then it is allowed to proceed such that between a target connected as cathode and an anode electric arc discharges are ignited, and with the energy thereof the target material will be transferred into plasma. The formed plasma is then allowed to reach on the surface of a substrate and to develop a layer there.

To avoid an uncontrolled motion of bases of ignited arc discharges along the surface of such a target which again results in an uncontrolled material abrasion of the target surface, laser light sources have been used. At the same time, with the laser pulses ejected from a laser light source a locally pointed ignition of electric arc discharges can be achieved by scanning the laser beam selectively across the surface of such a target. As a result, a more uniform material abrasion on the target surface can be achieved.

Such a technical solution is described, i.a., in DE 198 50 217 C1. The respective method is also referred to as “Laser-Arc method” in this field of technology.

For the ignition and development of the electric arc discharges one or else more targets, then preferably disposed in series, are connected as cathode. Then, above the surface of such targets an anode is disposed wherein the distance between the target surface and anode amounts only some few millimetres. The anode is connected to a respective electric potential.

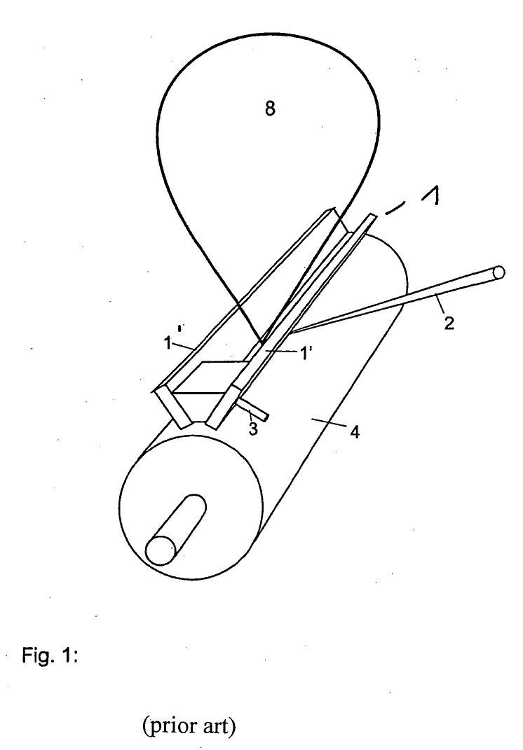

So far, it is common to use simple anodes which are formed from high-grade steel bars having a thickness of about 10 mm, and a depth of approx. 30 to 50 mm. Such an anode is shown diagrammatically in FIG. 1. For understandable reasons the anode bars should be dimensioned such that they being somewhat longer than a target and a plurality of targets disposed next to each other, respectively.

However, it is also known to use rotating water-cooled round anodes with a diameter ranging from 20 mm to 30 mm for the development of electric arc discharges for the plasma formation, starting from a target connected as cathode.

In particular with the “Laser-Arc method”, a lower coating rate is achieved as compared with different procedures in which plasma being generated by means of electric arc discharges.

In order to be able to confront this disadvantage there is a possibility of increase of the electric power. However, this raises the expenses considerably because of the electronic plants required for this such that any increase of the electric power is not readily possible.

Another problem with vacuum coating methods having plasmas generated due to electric arc discharges is in that even greater parts (droplets) can be embedded inside of the developing film such that the surface quality of such a developed film being deteriorated.

Starting from this, that's why it is an object of the invention to propose a possibility by means of which at least the coating rate can be increased without to substantially increase the effort related toward plant engineering required for this.

According to the invention, this object is solved with an anode having the features of claim 1. Advantageous embodiments and improvements of the invention can be achieved with the technical features indicated in the subordinate claims.

The anode according to the invention for the plasma formation through the development of electric arc discharges starting from a target connected as cathode, at the same time, is positioned in a distance to the target in a known manner. Then, at first there are anode bars being aligned in parallel to the surface of a target. In addition, strip-shaped elements being spaced from each other through gaps are formed on the anode. The strip-shaped elements then start from the anode bars, pointing in the direction of a substrate to be coated on the surface. As a result, the formed plasma is enclosed by two opposing sides with the strip-shaped elements of the anode. Between the anode bars there is a gap by means of which the formed plasma is allowed to pass through in the direction to a substrate to be coated.

The anode bars should be connected to each other in an electrically conducting manner.

As already touched on in the introducing part of the description, the anode according to the invention can also be used with the “Laser-Arc method”, wherein the ignition of the electric arc discharges can then be initiated in a locally differenced manner on the surface of targets with a laser beam being operated in a pulsed manner on the surface of the target.

It is of advantage to align the strip-shaped elements at an obliquely inclined angle such that the distance of opposing strip-shaped elements increases starting from the anode bar. Because of that, a plasma formation area conically diverging in the direction of the substrate can be developed.

Because of the gaps between strip-shaped elements of the anode, electrons drained away from the anode of the formed plasma are allowed to move only normal to the longitudinal axis of the anode, and as a result, develop a magnetic field H which is substantially in parallel to the longitudinal axis of the target(s), and in parallel to the anode bars, respectively. Because of that, it can be achieved that positive ions contained in excess in the plasma will be diffracted through the Lorentz-force of the developed magnetic field in the direction of the centre between strip-shaped elements.

Because the so accelerated electrons inside of the plasma themselves result in a strong electric current opposite to the plasma spreading direction, a concentric magnetic field H′ develops around the plasma being accelerated in the direction toward the substrate as well which again results in focussing the formed plasma between the strip-shaped elements of an anode according to the invention.

Thus, more massive particles or electrons as well are able to pass through the gaps developed between the strip-shaped elements. Such particles or other undesired plasma constituents can also be intercepted by means of shielding members. Such shielding members can be plate-like elements, for example, which are disposed in the area of the upper front sides of strip-shaped elements at the side next to them. Actually, the shielding members form apertures by means of which it can be avoided that these particles or plasma constituents separated from the plasma reach on the substrate surface to be coated, and causing in particular, adverse effects during the film development.

There is a possibility to use the strip-shaped elements in a parallel alignment on an anode according to the invention starting from the anode bars. Because of that, more or less, a parallel gap can be developed which then can form a plasma formation area.

However, it is more favourably to align the strip-shaped elements at an obliquely inclined angle how it has already been touched on. In this connection, a minimum angle at least of 10° relative to the plane being aligned normal to the target surface should be met.

It is also possible to form additional strip-shaped elements on the anode according to the invention, however, which are disposed in the area of the front ends of the anode bars. Because of that, the formed plasma is enclosed with strip-shaped elements not only by two opposite sides, but this also applies to the front side end areas. Thus, with the strip-shaped elements it is enabled to form a “cage” being open in the direction toward the surface of substrate to be deposited.

Further, there is a possibility at least to develop strip-shaped elements which are disposed on opposite sides of the anode such that they are formed concavely or convexly curved along their longitudinal axis. Because of such a curvature of strip-shaped elements a plasma formation area with a respective geometric configuration can be developed. With convex curvature of strip-shaped elements the plasma formation area expands in the direction to the substrate accordingly, which is opposite in the case of concave curvature of strip-shaped elements, so inside of the area of the front ends of strip-shaped elements facing toward the substrate, again a reduced gap width between oppositely disposed strip-shaped elements can be achieved.

Oppositely disposed strip-shaped elements are allowed to be arranged symmetrically to each other relative to the longitudinal axis of the anode bars such that two strip-shaped elements each are opposite. However, it is also possible for such strip-shaped elements to be staggered to each other such that a strip-shaped element on one side of the anode is opposite to a gap arranged on the other side of the anode.

The anode should be connected to an electrical power source preferably in the area of the anode bar, wherein it is particularly preferred to provide this contact on a front side end on the anode.

In particular with targets being very long in the direction of a longitudinal axis or of a corresponding arrangement of a plurality of such targets, of course there is also a possibility to provide several anodes according to the invention then preferably in an inline arrangement as well.

Gaps between strip-shaped elements being adjacently disposed to each other should be at least as wide as the respective strip-shaped elements.

However, the strip-shaped elements can also be formed diverging conically starting from the anode bars such that their respective width reduces successively, and consequently the gaps between strip-shaped elements being adjacently disposed to each other, starting from the anode bar to the front ends of strip-shaped elements facing in the direction of the substrate, are widened. By means of gaps being widened like that it is possible for the greater particles or other undesired constituents to be better separated from the plasma, and accordingly an undesired influence during the film formation on the substrate surface can be avoided.

With the anode according to the invention, the particle density in the coating developed on the substrate surfaces can be reduced by approximately 40%, and so the coating quality and in particular its surface coating grade can be distinctly improved. Additionally, the coating rate can be increased at least by 50%. With the development of diamond-like carbon coatings having a coating thickness of about 1 μm a modulus of elasticity being increased by 50% compared with commonly developed coatings of diamond-like carbon could be achieved.

With the activation of anodes for the ignition of electric arc discharges in a pulsed form, up to now high-current pulse sources are used the current peaks of which being up to about 3000 A and a pulse length of between 2 μs and 200 μs. Then, a circuitry is used in which an electrical power source charges an electric capacitor, and an inductive element is connected between this capacitor and the anode terminal or a target connected as cathode. In addition, a diode is connected in the circuit in parallel with the anode cathode path. As a result of the high electric currents the respective electric components should be water-cooled or intensively air-cooled what they even are, and which is of great disadvantage. With such a known solution fast changing of components or simply switching over between differently great components and consequently the fast variation is not readily possible. This means the pulse length and the current strength cannot be matched to the respective present method conditions in a simple manner.

With such a known circuitry, the per se known conditions of parallel-resonant circuits occur. Courses of the voltage and current result in that the capacitor, after oscillating over has occurred, can practically be recharged to 40 up to 60% of its output voltage again by means of the diode, after a double burning time of electric arc discharge. An electric arc discharge merely consumes up to 40% of the electric power accumulated in the capacitor. Because of that, there is a danger that an undesired ignition of an electric arc discharge due to ions and electrons being still available will be ignited between a chamber wall or the substrate, for example which is connected to a negative voltage and the anode. However, since recharging the capacitor to the required set voltage needs to occur shortly after an electric arc discharge it comes to a short circuit between electrical power source and the undesirably ignited electric arc discharges occasionally which results in considerable faults of the electrical power source. Electrical power sources have to be disconnected at least for a short duration then.

These disadvantages also occur with circuitries in which a plurality of such parallel-resonant circuits being connected to one electrical power source.

However, the disadvantages mentioned in advance can be eliminated by connecting an additional switch, preferably a solid-state switch, in series with the inductive element between the electric capacitor and a contact to an anode or a target connected as a cathode.

With such switches a purposeful separation of the discharge path of capacitors can be achieved. After disconnecting with such a switch shortly following an arc discharge, problem-free and complete recharging of a capacitor can take place without allowing a fault to occur. Ions or else electrons of a previous arc discharge being still present inside of a vacuum chamber cannot cause undesired retarded ignitions of electric arc discharges.

For example, fast IGBT switching devices or other power transistors can be used as switches. The control of such switches can take place by means of a timer control wherein the pulse length can be varied through decelerated energizing of discharge paths in several steps.

In the following, the invention shall be explained in more detail by way of example.

In the drawings,

FIG. 1 is a schematic representation of an anode according to the prior art;

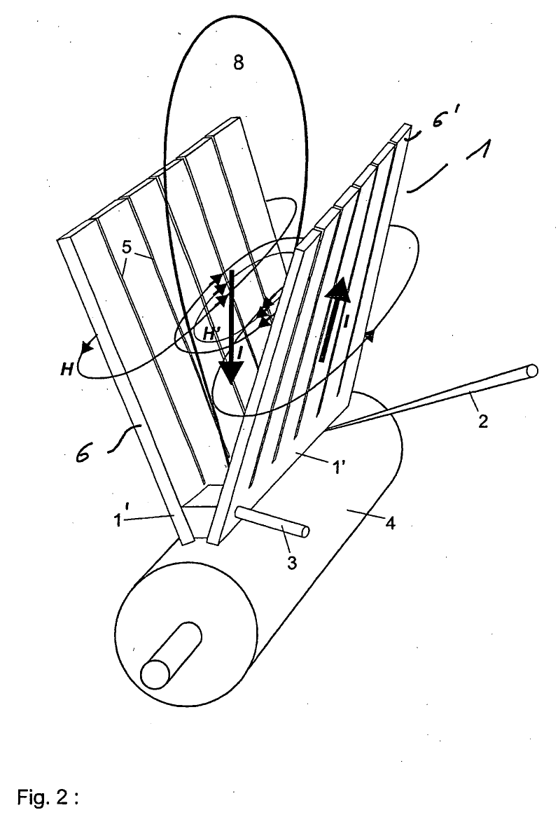

FIG. 2 is an embodiment of an anode according to the invention in a schematic representation; and

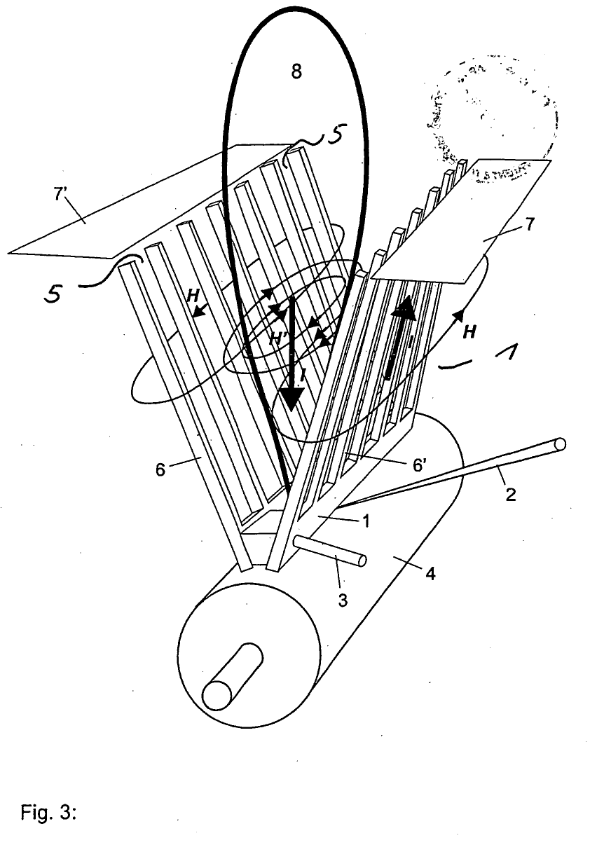

FIG. 3 is another embodiment of an anode according to the invention having additional shielding members.

In FIG. 1 is shown an arrangement with one anode 1 according to the prior art. Then, the anode 1 consisting of two elements made of stainless steel in the form of anode bars 1′ having a thickness of about 10 millimetres and a width of 30 to 50 millimetres is disposed in a distance of a few millimetres above a cylindrical target 4 being connected as cathode. Between the two anode bars 1′ of the anode 1 which are aligned to each other at an obliquely inclined angle here a gap is formed through which a plasma 8 developed by the target 4 is allowed to pass in the direction toward a substrate not shown herein, and to be used for the surface coating thereof.

From FIG. 1 it is also evident that a laser beam 2 emitted from a laser light source can be directed to the surface of the target 4. By means of the pulsed operation of the laser beam 2, and at the same time of simultaneous deflection it is allowed to locally ignite electric arc discharges in a defined manner between the target 4 and the anode bars 1′, and then to use for the plasma formation. The base of the ignited electric arc discharges can so be varied specifically, and a uniform material abrasion across the entire surface of the target 4 can be achieved. Here, a terminal contact 3 is present on a front end of the anode 1 by means of which the anode 1 can be connected with an electrical power source also not shown herein.

With FIG. 2 an embodiment according to the invention shall be explained in more detail.

Then, an anode 1 according to the invention is formed such that, starting from anode bars 1′, the anode 1 is lengthened with strip-shaped elements 6 and 6′ in the direction to a substrate also not shown herein. Gaps 5 are formed between the strip-shaped elements 6 and 6′.

The other elements correspond with those as they have been already illustrated and explained in the embodiment in accordance with the prior art according to FIG. 1.

The electrons drained away with the anode 1 from the formed plasma 8 are allowed to drain off only normal to the longitudinal axis by means of the strip-shaped elements 6 and 6′ as well as the gaps 5 being formed between them, and thus generate the magnetic field H which is largely formed in parallel to the longitudinal axis of the anode bars 1′ and the target. Because of that, the path of the positive ions being present in excess in the formed plasma 8 is allowed to be diffracted by the Lorentz-force toward the centre of the plasma 8.

As the accelerated electrons in plasma 8 themselves result, within the expanding plasma 8, in a powerful electric current in the propagation direction of the plasma 8, more intensely than the excessive but more massive ions, a concentric magnetic field H′ is also forming around the plasma 8 accelerated in the direction to the substrate. The magnetic field H′ result in further focussing of the plasma 8.

With this embodiment an anode 1 according to the invention has been fabricated from stainless steel by means of a laser cutting method. The strip-shaped elements 6 and 6′ then have a length of 200 millimetres starting from the front side facing in the direction of target 4, thus the front side of the anode bars 1′. They also have a thickness of 4 millimetres. The gap width between the individual strip-shaped elements 6 and 6′ has amounted to 26 millimetres. Between the anode bars 1′ a gap is formed through which the developed plasma 8 is allowed to pass through starting from the target 4 in the direction to a substrate also not shown herein, and to be used for the surface coating thereof.

As will be seen from FIG. 2, the two lines of strip-shaped elements 6 and 6′ can be aligned to each other at an obliquely inclined angle. With this anode 1 the angle relative to the normal plane between the two lines of strip-shaped elements 6 and 6′ has amounted to 15°.

Anode 1 is connected to a power source via terminal 3. From there, a voltage to the amount of 140 V is applied. The anode has been operated with a maximum current strength of 2000 A.

With the embodiments shown in FIG. 2 and also in FIG. 3, a target 4 made of pure carbon has been used by means of which a substrate can be coated with diamond-like carbon on a surface.

In a form being not shown, however, a plurality of such cylindrical targets 4 can be disposed along the longitudinal axis about which they rotate then, and can be formed from different materials such that, as touched on in the introducing part of the description, multi-layer systems can also be developed on surfaces of substrates without requiring additional effort related to plant engineering for replacement of individual elements or transport of a substrate each to be deposited.

Contrary to the description in FIG. 2 and FIG. 3 an anode 1 according to the invention should correspond at least approximately to the length of a target 4 or to the overall length of an in-line arrangement of a plurality of targets 4, however, should preferably be some longer.

The embodiment of an anode 1 according to the invention shown in FIG. 3 differs in two respects from the embodiment according to FIG. 2. Then, the gaps 5 between the strip-shaped elements 6 and 6′ have been enlarged such that the distance between adjacently disposed strip-shaped elements 6 or 6′ is enlarged too as with the embodiment of an anode 1 shown in FIG. 1.

Additionally, at the side next to the anode in the area of the upper front ends of strip-shaped elements 6 and 6′, plate-like shielding members 7 and 7′ have been disposed here. Thus, the surface of the shielding members 7 and 7′ facing in the direction to the target 4 herein, can be used to catch particles or other undesired constituents from the developed plasma 8 which have passed through the gaps 5, and thus to protect the surface of a substrate to be coated by means of the shielding members 7 and 7′ from these particles or plasma constituents.

It is obvious that the shielding members 7 and 7′ can be aligned at a slightly obliquely inclined angle as well, however, wherein the surface should be aligned such that particles or undesired constituents from the plasma 8 can reliably be caught.

The shielding members 7 and 7′ can also be placed on an electrically positive electric potential to improve their protective effect.

1. An anode for the formation of a plasma by means of the development of electric arc discharges, starting from a target connected as cathode for coating of substrates with target material in a vacuum, wherein said anode is disposed to the target in a distance, characterised in that said anode (1) is formed, starting from anode bars (1′) being aligned in parallel to the surface of said target (4), with strip-shaped elements (6, 6′) which are separated from each other by gaps (5), and plasma (8) developed from said target (6) is enclosed with said strip-shaped elements (6, 6′) from at least two opposite sides, and between said anode bars (1′) a gap is present through which said formed plasma (8) passes through in the direction of a substrate to be coated.

2. The anode according to claim 1, characterised in that for the ignition of electric arc discharges a laser beam (2) operated in a pulsed manner is directed to the surface of said target (4).

3. The anode according to claim 1, characterised in that said strip-shaped elements (6, 6′) are aligned at an angle such that the distance of said oppositely disposed strip-shaped elements enlarges starting from said anode bars (1′).

4. The anode according to claim 1, characterised in that said strip-shaped elements (6, 6′) form a front side sealing in the area of the front ends of said anode bars (1′).

5. The anode according to claim 1, characterised in that said strip-shaped elements (6, 6′), starting from said anode bars (1′), are formed concavely or convexly curved along their longitudinal axis.

6. The anode according to claim 1, characterised in that said strip-shaped elements (6, 6′) are arranged symmetrically to each other relative to the longitudinal axis of said anode (1).

7. The anode according to claim 1, characterised in that said strip-shaped elements (6, 6′) are not arranged symmetrically to each other relative to the longitudinal axis of said anode (1).

8. The anode according to claim 1, characterised in that said strip-shaped elements (6, 6′) oppositely arranged relative to said anode bars (1′) are staggered to each other.

9. The anode according to claim 1, characterised in that said anode (1) in the area of said anode bars (1′) is connected to an electrical power source.

10. The anode according to claim 1, characterised in that shielding members (7, 7′) are disposed at the side next to and in the area of the upper front sides of said strip-shaped elements (6, 6′).

11. The anode according to claim 1, characterised in that said strip-shaped elements (6, 6′) are connected with each other on the front side opposing to said anode bars (1′).

12. The anode according to claim 1, characterised in that said strip-shaped elements (6, 6′), starting from said anode bars (1′), are formed conically diverging, and said gaps (5), starting from said anode bars (1′), are widening between said strip-shaped elements (6, 6′) being disposed next to each other.

13. The anode according to claim 1, characterised in that said oppositely disposed strip-shaped elements (6, 6′) are aligned at an angle such that between them a plasma formation area conically diverging in the direction of said substrate is formed.

14. The anode according to claim 1, characterised in that the distance between said strip-shaped elements (6, 6′) reduces in the direction to said substrate starting from said anode bars (1′).
